(19) United States
(12) Patent Application Publication
(10) Pub. No.: US 2024/0237186 A9
(43) Pub. Date: Jul. 11, 2024

(54) POWER SUPPLY DEVICE HAVING THERMAL INSULATION FUNCTION

(71) Applicant: ELEMENTS PERFORMANCE TECHNOLOGY INC., KAOHSIUNG CITY (TW)

(72) Inventors: JERRYSON LEE, KAOHSIUNG CITY (TW); Ethan Lee, KAOHSIUNG CITY (TW); Yu-Jia Huang, KAOHSIUNG CITY (TW); KUO-SUNG HUANG, KAOHSIUNG CITY (TW)

(21) Appl. No.: 18/313,358

(22) Filed: May 7, 2023

(30) Foreign Application Priority Data
Oct. 21, 2022 (TW) 111139948

(51) Int. Cl. H05K 1/02; F21V 23/02; H05K 1/18

(52) U.S. Cl. CPC H05K 1/0201; F21V 23/02; H05K 1/18; F21Y 2115/10; H05K 2201/062; H05K 2201/10015

(57) ABSTRACT

A power supply device having a thermal insulation function includes a circuit board, and at least one heat-sensitive component and a plurality of heat-generating electronic components that are disposed on the circuit board and spaced apart from one another. The heat-generating electronic components include a transformer, an inductor, an integrated circuit, or a metal oxide semiconductor (MOS). A minimum distance between the heat-sensitive component and the heat-generating electronic components is 7 mm. A thermal insulation area is defined between the heat-sensitive component and the heat-generating electronic components, and none of the heat-generating electronic components is disposed within a 270° range of the thermal insulation area. The heat-generating electronic components are disposed outside the thermal insulation area to separate the heat-sensitive component from a heat source on the circuit board, such that a high temperature of the heat source has less influence on the heat-sensitive component.

### CROSS-REFERENCE TO RELATED PATENT APPLICATION

This application claims the benefit of priority to Taiwan Patent Application No. 111139948, filed on Oct. 21, 2022. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a thermal insulation device, and more particularly to a power supply device having a thermal insulation function and being capable of converting an alternating current (AC) to a direct current (DC).

### BACKGROUND OF THE DISCLOSURE

A conventional light fixture provides lighting by an incandescent light bulb, a fluorescent lamp, a mercury-vapor bulb, or a halogen bulb. In recent years, with the improvement of diode technology, light-emitting diodes (LED) with high power and high luminosity have been released one after another, and have well begun replacing other conventional light sources. Since a diode is driven by a direct current (DC), an electronic circuit is usually installed in an LED light fixture, so as to convert an alternating current (AC) used in everyday life to the direct current (DC) and provide electricity to the LED within the light fixture.

An existing power conversion device includes heat-generating electronic components (e.g., a transformer, an inductor, an integrated circuit, and a metal oxide semiconductor (MOS)), which tend to generate heat of high temperature during operation. As a result, a heat-sensitive component (e.g., a capacitor) that has a low heat resistance can be seriously affected, and the service life of the heat-sensitive component may decrease as the operating temperature is increased. Since the heat-sensitive component (e.g., a capacitor) and the heat-generating electronic components are disposed on the same circuit board, the service life of the heat-sensitive component is significantly shortened. For example, the heat generated by an electrolytic capacitor can accelerate the depletion of an electrolyte and cause the electrolyte to dry up, or even cause boiling of the electrolyte and result in an explosion. Furthermore, the drying up of the electrolyte leads to poor endurance against a ripple current, such that the service life of the capacitor is rapidly shortened.

### SUMMARY OF THE DISCLOSURE

In response to the above-referenced technical inadequacies, the present disclosure provides a power supply device having a thermal insulation function, which can isolate a heat-sensitive component from a heat-generating electronic component on a circuit board, so as to prevent a high temperature from negatively affecting a service life and performance of the heat-sensitive component.

In order to solve the above-mentioned problems, one of the technical aspects adopted by the present disclosure is to provide a power supply device having a thermal insulation function. The power supply device includes: a circuit board; at least one heat-sensitive component disposed on and electrically connected to the circuit board; and a plurality of heat-generating electronic components disposed on and electrically connected to the circuit board. The at least one heat-sensitive component is spaced apart from the heat-generating electronic components, a thermal insulation area is defined between the at least one heat-sensitive component and the heat-generating electronic components, none of the heat-generating electronic components is disposed within a 270° range of the thermal insulation area, and a minimum distance between the at least one heat-sensitive component and the heat-generating electronic components is 7 mm.

In one of the possible or preferred embodiments, the heat-generating electronic components include a transformer, an inductor, an integrated circuit, or a metal oxide semiconductor, and a temperature generated during operation of each of the heat-generating electronic components is greater than a temperature generated during operation of the at least one heat-sensitive component.

In order to solve the above-mentioned problems, another one of the technical aspects adopted by the present disclosure is to provide a power supply device having a thermal insulation function, which is used to convert an alternating current to a direct current. The power supply device includes: a circuit board having a first surface and a second surface; at least one heat-sensitive component disposed on the first surface of the circuit board and electrically connected to the circuit board; and a plurality of heat-generating electronic components disposed on the first surface of the circuit board and electrically connected to the circuit board. The first surface and the second surface are respectively positioned on two opposite surfaces of the circuit board. The at least one heat-sensitive component is spaced apart from the heat-generating electronic components, a thermal insulation area is defined between the at least one heat-sensitive component and the heat-generating electronic components, none of the heat-generating electronic components is disposed within a 270° range of the thermal insulation area, and a minimum distance between the at least one heat-sensitive component and the heat-generating electronic components is 7 mm.

In order to solve the above-mentioned problems, yet another one of the technical aspects adopted by the present disclosure is to provide a power supply device having a thermal insulation function. The power supply device includes: a circuit board; at least one heat-sensitive component; and a plurality of heat-generating electronic components. The at least one heat-sensitive component has a heat-sensitive component body and a plurality of heat-sensitive component pins, the heat-sensitive component pins are connected to the heat-sensitive component body, and the at least one heat-sensitive component is disposed on and electrically connected to the circuit board. Each of the heat-generating electronic components has a heat-generating electronic component body and a plurality of heat-generating electronic component pins, the heat-generating electronic component pins are connected to the heat-generating electronic component body, and the heat-generating electronic components are disposed on and electrically connected to the circuit board. The at least one heat-sensitive component is spaced apart from the heat-generating electronic components, a thermal insulation area is defined between the at least one heat-sensitive component and the heat-generating electronic components, and none of the heat-generating electronic components is disposed within a 270° range of the thermal insulation area. A minimum distance between the heat-sensitive component body and the heat-generating electronic component bodies is 7 mm, or a minimum distance between the heat-sensitive component pins and the heat-generating electronic component bodies is 7 mm.

Therefore, in the power supply device having the thermal insulation function provided by the present disclosure, the power supply device includes the circuit board, the at least one heat-sensitive component, and the heat-generating electronic components. The at least one heat-sensitive component is spaced apart from the heat-generating electronic components, the thermal insulation area is defined between the at least one heat-sensitive component and the heat-generating electronic components, none of the heat-generating electronic components is disposed within the 270° range of the thermal insulation area, and the minimum distance between the at least one heat-sensitive component and the heat-generating electronic components is 7 mm. The heat-generating electronic components are disposed outside the thermal insulation area, so as to separate and effectively isolate the at least one heat-sensitive component from a heat source (i.e., the heat-generating electronic components) on the circuit board. In this way, a high temperature of the heat source has less influence on the at least one heat-sensitive component. During operation, heat energy generated by the heat source does not negatively affect a service life and performance of the at least one heat-sensitive component by virtue of thermal conduction and thermal convection.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic top view of a power supply device having a thermal insulation function according to one embodiment of the present disclosure;

FIG. 2 is a schematic perspective view of the power supply device having the thermal insulation function according to the embodiment of the present disclosure;

FIG. 3 is a circuit diagram illustrating conversion of an alternating current to a direct current according to the present disclosure;

FIG. 4 is a schematic top view of the power supply device having the thermal insulation function according to another embodiment of the present disclosure; and

FIG. 5 is a schematic top view of the power supply device having the thermal insulation function according to yet another embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### Embodiments

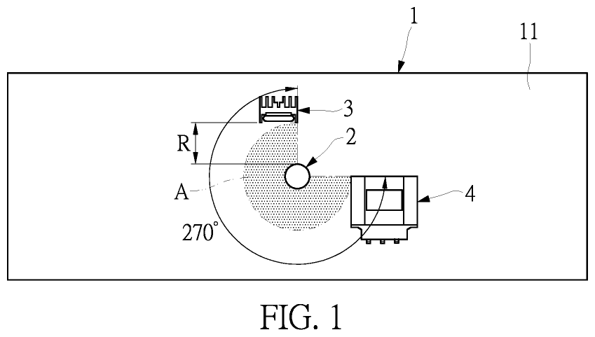

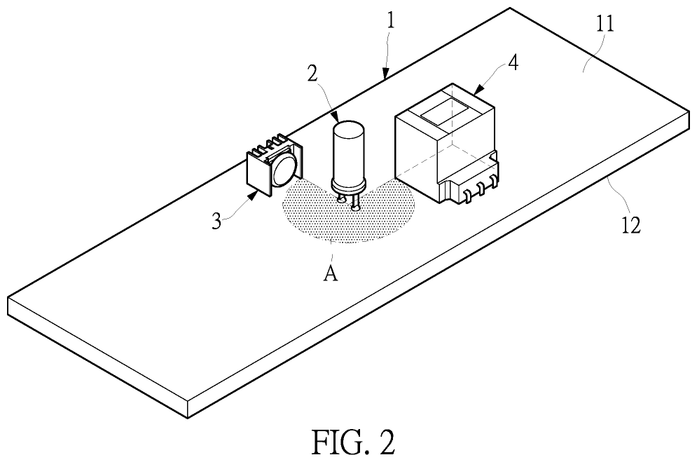

Referring to FIG. 1 and FIG. 2, the present disclosure provides a power supply device having a thermal insulation function. The power supply device can be applied to devices such as a light-emitting diode (LED) light fixture, and is used to convert an alternating current (AC) to a direct current (DC). The power supply device can perform operations that include rectification and voltage reduction on a power source, so as to provide an electric power required by the devices such as the LED light fixture. Preferably, a power of the LED light fixture is less than 2,000 W. The power supply device includes a circuit board 1, at least one heat-sensitive component 2, and a plurality of heat-generating electronic components 3, 4.

The circuit board 1 can be a printed circuit board, and has a first surface 11 and a second surface 12. The first surface 11 and the second surface 12 are positioned on two opposite surfaces of the circuit board 1, respectively.

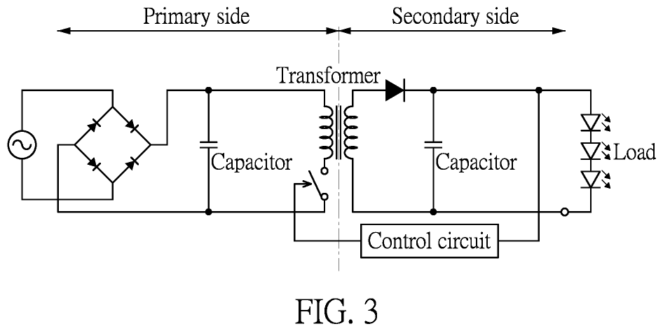

The quantity of the heat-sensitive component 2 can be one or more than one (e.g., two, three, or four), which is not limited in the present disclosure. The heat-sensitive component 2 can be a capacitor, but is not limited thereto. The capacitors are usually disposed at a primary side and a secondary side of the power supply device (as shown in FIG. 3). That is, the capacitors are disposed before and after a transformer. The capacitor of the present disclosure (i.e., the heat-sensitive component 2) refers to the capacitor being disposed at the secondary side of the transformer (i.e., the capacitor disposed after the transformer).

The heat-sensitive component 2 is disposed on the circuit board 1 (a cold area). The heat-sensitive component 2 is disposed on the first surface 11 of the circuit board 1, and is electrically connected to the circuit board 1. The heat-sensitive component 2 can be disposed on and electrically connected to the circuit board 1 by way of mating, soldering, etc.

The heat-generating electronic components 3, 4 are disposed on the circuit board 1 (a hot area). The heat-generating electronic components 3, 4 are disposed on the first surface 11 of the circuit board 1, and are electrically connected to the circuit board 1. The heat-generating electronic components 3, 4 can be disposed on and electrically connected to the circuit board 1 by way of mating, soldering, etc.

The heat-generating electronic components 3, 4 can include a transformer, an inductor, an integrated circuit, or a metal oxide semiconductor (MOS). A temperature generated during operation of each of the heat-generating electronic components 3, 4 is greater than a temperature generated during operation of the heat-sensitive component 2. The quantity and the type of the heat-generating electronic components 3, 4 are not limited in the present disclosure, and can be changed according to practical requirements. Further, a thermal insulation adhesive or a thermal insulation material can be disposed between the heat-generating electronic components 3, 4 and the heat-sensitive component 2, so as to improve a thermal insulation effect. According to practical requirements, various electronic components (not labeled) can also be disposed on the circuit board 1.

The heat-sensitive component 2 is spaced apart from the heat-generating electronic components 3, 4. A minimum distance R between the heat-sensitive component 2 and the heat-generating electronic components 3, 4 is 7 mm (which can be, for example, 7 mm, 8 mm, 9 mm, 10 mm, 11 mm, or 20 mm) A thermal insulation area A is defined between the heat-sensitive component 2 and the heat-generating electronic components 3, 4, and none of the heat-generating electronic components 3, 4 is disposed within a 270° range of the thermal insulation area A. That is, none of the heat-generating electronic components 3, 4 is disposed within the 270° range of the thermal insulation area A that has the heat-sensitive component 2 at its center.

In the present disclosure, the heat-generating electronic components 3, 4 are not disposed within a range of three-quarters (270 degrees) of a circle, such that the heat-sensitive component 2 can have a large thermal insulation space. The heat-generating electronic components 3, 4 are disposed outside the thermal insulation area A, so as to separate the heat-sensitive component 2 from a heat source (i.e., the heat-generating electronic component 3, 4) on the circuit board 1. In this way, a high temperature of the heat source has less influence on the heat-sensitive component 2. While electronic components that do not generate heat can be disposed in the thermal insulation area A, it is preferable that no component be disposed in the thermal insulation area A. That is, the thermal insulation area A is a vacant area, so as to achieve an improved heat dissipation effect.

During operation, heat energy generated by the heat source does not negatively affect a service life and performance of the heat-sensitive component 2 through thermal conduction and thermal convection. The circuit board 1 can be properly fixed to the LED light fixture or a housing of a power conversion device by a dispensing process or by use of a fixing member, such that the power supply device is fixed in a stable manner. A thermal insulation method of the present disclosure can be used in a typical AC-to-DC power conversion device, which can be the LED light fixture (e.g., a shelf light or a high bay light). The type of the LED light fixture is not limited thereto.

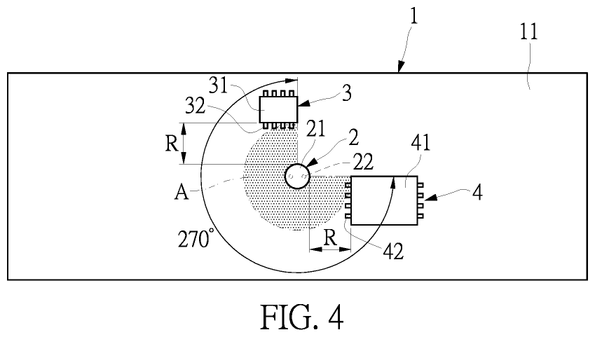

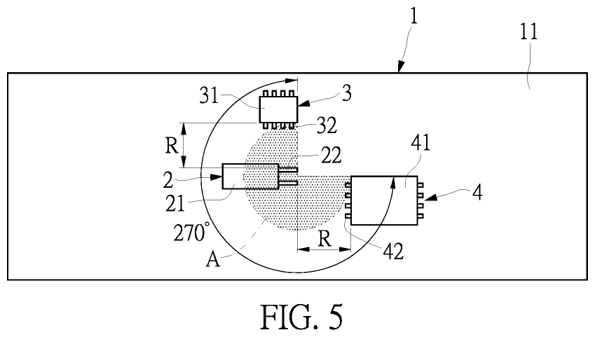

Reference is made to FIG. 4 and FIG. 5. In the present embodiment, the heat-sensitive component 2 has a heat-sensitive component body 21 and a plurality of heat-sensitive component pins 22. The heat-sensitive component pins 22 are connected to the heat-sensitive component body 21, and the heat-sensitive component 2 is disposed on and electrically connected to the circuit board 1. The heat-sensitive component 2 is electrically connected to the circuit board 1 via the heat-sensitive component pins 22. The heat-sensitive component 2 can be disposed on the circuit board 1 in an upright manner (as shown in FIG. 4) or in a horizontal manner (as shown in FIG. 5).

Each of the heat-generating electronic components 3, 4 has a heat-generating electronic component body 31, 41 and a plurality of heat-generating electronic component pins 32, 42. The heat-generating electronic component pins 32, 42 are connected to the heat-generating electronic component bodies 31, 41, respectively. The heat-generating electronic components 3, 4 are disposed on and electrically connected to the circuit board 1. The heat-generating electronic components 3, 4 are electrically connected to the circuit board 1 via the heat-generating electronic component pins 32, 42. The heat-sensitive component 2 is spaced apart from the heat-generating electronic components 3, 4. The thermal insulation area A is defined between the heat-sensitive component 2 and the heat-generating electronic components 3, 4, and none of the heat-generating electronic components 3, 4 is disposed within the 270° range of the thermal insulation area A. When the heat-sensitive component 2 is disposed in the upright manner, the minimum distance R between the heat-sensitive component body 21 and the heat-generating electronic component bodies 31, 41 is 7 mm (as shown in FIG. 4). Alternatively, when the heat-sensitive component 2 is disposed in the horizontal manner, the minimum distance R between the heat-sensitive component pins 22 and the heat-generating electronic component bodies 31, 41 is 7 mm (as shown in FIG. 5).

### Beneficial Effects of the Embodiments

In conclusion, in the power supply device having the thermal insulation function provided by the present disclosure, the power supply device includes a circuit board, at least one heat-sensitive component, and a plurality of heat-generating electronic components. The heat-sensitive component is spaced apart from the heat-generating electronic components, a thermal insulation area is defined between the heat-sensitive component and the heat-generating electronic components, none of the heat-generating electronic components is disposed within a 270° range of the thermal insulation area, and a minimum distance between the heat-sensitive component and the heat-generating electronic components is 7 mm. The heat-generating electronic components are disposed outside the thermal insulation area, so as to separate and effectively isolate the heat-sensitive component from the heat source (i.e., the heat-generating electronic components) on the circuit board. In this way, the high temperature of the heat source has less influence on the heat-sensitive component. During operation, the heat energy generated by the heat source does not negatively affect a service life and performance of the heat-sensitive component by virtue of thermal conduction and thermal convection.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A power supply device having a thermal insulation function, comprising:
a circuit board;
at least one heat-sensitive component disposed on and electrically connected to the circuit board; and
a plurality of heat-generating electronic components disposed on and electrically connected to the circuit board;
wherein the at least one heat-sensitive component is spaced apart from the heat-generating electronic components, a thermal insulation area is defined between the at least one heat-sensitive component and the heat-generating electronic components, none of the heat-generating electronic components is disposed within a 270° range of the thermal insulation area, and a minimum distance between the at least one heat-sensitive component and the heat-generating electronic components is 7 mm.

2. The power supply device according to claim 1, wherein the at least one heat-sensitive component is a capacitor.

3. The power supply device according to claim 1, wherein the heat-generating electronic components include a transformer, an inductor, an integrated circuit, or a metal oxide semiconductor, and a temperature generated during operation of each of the heat-generating electronic components is greater than a temperature generated during operation of the at least one heat-sensitive component.

4. The power supply device according to claim 1, wherein the circuit board has a first surface and a second surface, the first surface and the second surface are respectively positioned on two opposite surfaces of the circuit board, and the at least one heat-sensitive component and the heat-generating electronic components are disposed on the first surface of the circuit board.

5. The power supply device according to claim 1, wherein the thermal insulation area is a vacant area.

6. The power supply device according to claim 1, wherein the power supply device is applied to a light-emitting diode light fixture for converting an alternating current to a direct current, and a power of the light-emitting diode light fixture is less than 2,000 W.

7. The power supply device according to claim 1, wherein the at least one heat-sensitive component is disposed at a secondary side of a transformer.

8. A power supply device having a thermal insulation function, which is used to convert an alternating current to a direct current, the power supply device comprising:
a circuit board having a first surface and a second surface, wherein the first surface and the second surface are respectively positioned on two opposite surfaces of the circuit board;
at least one heat-sensitive component disposed on the first surface of the circuit board and electrically connected to the circuit board; and
a plurality of heat-generating electronic components disposed on the first surface of the circuit board and electrically connected to the circuit board;
wherein the at least one heat-sensitive component is spaced apart from the heat-generating electronic components, a thermal insulation area is defined between the at least one heat-sensitive component and the heat-generating electronic components, none of the heat-generating electronic components is disposed within a 270° range of the thermal insulation area, and a minimum distance between the at least one heat-sensitive component and the heat-generating electronic components is 7 mm.

9. The power supply device according to claim 8, wherein the at least one heat-sensitive component is a capacitor.

10. The power supply device according to claim 8, wherein the heat-generating electronic components include a transformer, an inductor, an integrated circuit, or a metal oxide semiconductor, and a temperature generated during operation of each of the heat-generating electronic components is greater than a temperature generated during operation of the at least one heat-sensitive component.

11. The power supply device according to claim 8, wherein the at least one heat-sensitive component is disposed at a secondary side of a transformer.

12. The power supply device according to claim 8, wherein the thermal insulation area is a vacant area.

13. A power supply device having a thermal insulation function, comprising:
a circuit board;
at least one heat-sensitive component, wherein the at least one heat-sensitive component has a heat-sensitive component body and a plurality of heat-sensitive component pins, the heat-sensitive component pins are connected to the heat-sensitive component body, and the at least one heat-sensitive component is disposed on and electrically connected to the circuit board; and
a plurality of heat-generating electronic components, wherein each of the heat-generating electronic components has a heat-generating electronic component body and a plurality of heat-generating electronic component pins, the heat-generating electronic component pins are connected to the heat-generating electronic component body, and the heat-generating electronic components are disposed on and electrically connected to the circuit board;
wherein the at least one heat-sensitive component is spaced apart from the heat-generating electronic components, a thermal insulation area is defined between the at least one heat-sensitive component and the heat-generating electronic components, and none of the heat-generating electronic components is disposed within a 270° range of the thermal insulation area; wherein a minimum distance between the heat-sensitive component body and the heat-generating electronic component bodies is 7 mm, or a minimum distance between the heat-sensitive component pins and the heat-generating electronic component bodies is 7 mm.

14. The power supply device according to claim 13, wherein the at least one heat-sensitive component is a capacitor.

15. The power supply device according to claim 13, wherein the heat-generating electronic components include a transformer, an inductor, an integrated circuit, or a metal oxide semiconductor, and a temperature generated during operation of each of the heat-generating electronic components is greater than a temperature generated during operation of the at least one heat-sensitive component.

16. The power supply device according to claim 13, wherein the circuit board has a first surface and a second surface, the first surface and the second surface are respectively positioned on two opposite surfaces of the circuit board, and the at least one heat-sensitive component and the heat-generating electronic components are disposed on the first surface of the circuit board.

17. The power supply device according to claim 13, wherein the thermal insulation area is a vacant area.

18. The power supply device according to claim 13, wherein the power supply device is applied to a light-emitting diode light fixture for converting an alternating current to a direct current, and a power of the light-emitting diode light fixture is less than 2,000 W.

19. The power supply device according to claim 13, wherein the at least one heat-sensitive component is disposed at a secondary side of a transformer.
